(19) United States
(12) Patent Application Publication
(10) Pub. No.: US 2026/0257573 A1
(43) Pub. Date: Sep. 3, 2026

(54) POWER CONVERSION ARRANGEMENT WITH COOLING FAN

(71) Applicant: BRUSA ELEKTRONIK AG, Buchs (CH)

(72) Inventor: Veit PFÄTTISCH, Buchs (CH)

(21) Appl. No.: 19/491,259

(22) PCT Filed: Jun. 17, 2024
(86) PCT No.: PCT/EP2024/066828

§ 371 Date: Dec. 8, 2025

(30) Foreign Application Priority Data
Jun. 22, 2023 (DE) 10 2023 116 495.3

(51) Int. Cl. B60L 53/302; B60L 53/12; F04D 17/08; F04D 29/28

(52) U.S. Cl. CPC B60L 53/302; B60L 53/12; F04D 17/08; F04D 29/281

(57) ABSTRACT

A power conversion arrangement serves as a wireless charging station (ground pad module) for the energy supply of a wireless charging device of an electrical vehicle. It comprises a magnetic subassembly, an electronic subassembly, and as heat dissipation means with a radial fan for cooling the magnetic subassembly and/or the electronic subassembly. The radial fan with a fan wheel conveys the air into at least one outlet channel past at least one cutoff edge. The cutoff edge with regard to a rotation axis of the radial fan and in a region of proximity to the fan wheel is angled about an angle, denoted herein as an effective edge angle (k) of at least twenty degrees.

### CROSS REFERENCE TO RELATED APPLICATIONS

The present application is the U.S. National Phase of PCT/EP 2024/066828, filed on 17 Jun. 2024, which claims priority to German Patent Application No. 10 2023 116 495.3, filed on 22 Jun. 2023, the entire contents of which are incorporated herein by reference.

### BACKGROUND

### Field

The present invention relates to power conversion arrangement for converting the electrical power of an electrical feed current into electromagnetic power of an oscillating electromagnetic field. The power conversion arrangement comprises a magnetic subassembly for receiving an electrical alternating current and for emitting an oscillating electromagnetic field, as well as an electronic subassembly for receiving the electrical feed current and for its conversion into an electrical alternating current for the supply of a magnetic subassembly. The power conversion arrangement further comprises heat dissipation means for dissipating heat which is generated by the electronic subassembly and/or the magnetic subassembly during its respective power conversion operation.

### Related Art

The power conversion arrangement which is also denoted as a wireless charging station or as a ground pad module (GPM) can be applied for the energy supply of a wireless charging device, also denoted as a car pad module (CPM). Such a CPM can receive the oscillating electromagnetic, predominantly magnetic field from the GPM, convert it into an alternating current, convert this further (typically rectify it) and from this form a charging current (typically direct current) which is used for charging a traction battery of a vehicle.

Batteries of electrical vehicles can be charged with alternating current (AC) or direct current (DC). Typical AC charging devices can provide a charging power of up to 22 kW. AC charging systems can be subdivided into cable-connected charging systems and cableless charging systems, wherein cableless charging systems are predominantly designed as inductive charging systems (ICS). As a rule, an ICS consists of two separate modules which are often denoted as a ground pad module (GPM) and car pad module (CPM). The GPM is installed outside the electrical vehicle, whereas the CPM is attached in the inside of an electrical vehicle and as a rule on the underside of the vehicle. The electromagnetic interaction between the GPM and the CPM permits the energy transmission from the GPM to the CPM, and the CPM in turn is used for charging a battery of the electrical vehicle. Cableless charging systems are often more conformable for the user since as a rule no manual intervention is necessary in order to start the charging procedure of the battery, apart from placing the vehicle over the GPM.

A GPM typically comprises a magnetic subassembly and an electronic subassembly. The magnetic subassembly comprises a coil and ferrite elements which heat up on operation of the GPM and need to be cooled. The electronic subassembly likewise needs to be cooled. The magnetic subassembly and the electrical subassembly can be arranged in a common housing or in separate, functionally coupled modules. An air cooling with one or more radial fans can be arranged for cooling the electronic assembly and/or the magnetic subassembly. Radial fans lead to annoying noise emissions.

### SUMMARY

It is therefore the object of the invention to provide a power conversion arrangement of the initially mentioned type, with a radial fan with reduced noise emissions.

This object is achieved by a power conversion arrangement with the features of patent claim 1.

The power conversion arrangement serves for the conversion of the electrical power of an electrical feed current into electromagnetic power of an oscillating electromagnetic field. It comprises:
a magnetic subassembly for receiving or delivering an electrical alternating current and/or for emitting an oscillating electromagnetic field, as well as
an electronic subassembly for receiving the electrical feed current and for its conversion into an electrical alternating current for the supply of the magnetic subassembly,
heat dissipation means for dissipating heat which is generated by the electronic subassembly and/or the magnetic subassembly during its respective power conversion operation.

Herein, it is the case that the heat dissipation means comprise at least one radial fan which is arranged for the conveying of air for cooling the magnetic and/or the electronic subassembly, wherein the radial fan with a fan wheel conveys the air into at least one outlet channel past at least one cutoff edge, wherein the cutoff edge with regard to a rotation axis of the radial fan and in a region of proximity to the fan wheel is angled about an angle, hereinafter denoted as the effective edge angle, in particular about an effective edge angle of at least twenty degrees.

With regard to a radial fan, the cut-off edge is the part of the fan housing at the outlet which is closest to the blade tips of the fan wheel. A conventional separation has a straight edge parallel to the blade tips, whereas the edges of a V-notch run obliquely to the blade tips.

Edge angles, for example, can be measured in a projection of the cutoff edge along the direction of a straight line of connection between the cutoff edge and the rotation axis. The projection can be effected onto a plane which contains the rotation axis and lies normally to the straight line of connection. If the cutoff edge in this projection does not run in a straight line in a section of the cutoff edge, then a compensation straight line (regression straight line) is made through this projection. The angle of this compensation straight line relative to the rotation axis is considered as the average edge angle in this section.

The effective edge angle is denoted as such since the respective section of the cutoff edge lies in the region of proximity to the fan wheel and herewith has a large influence on the flow and on the development of noise. The effective edge angle can be defined as the average edge angle in the region of proximity. It can also be designed as the average edge angle in a region up to half the height of the fan wheel.

By way of the cutoff edge being angled as described above, in the region of proximity it leads away from the fan wheel to a remote region. The greater the cutoff edge is distanced to the fan wheel, the smaller is the eddying and noise emissions, but at the cost of the conveying performance. A compromise between these contradictory demands can be found by the selection of the effective edge angle in the region of proximity.

The magnetic subassembly and the electronic subassembly are functionally connected to one another by way of them exchanging electrical energy. They can be arranged in a common housing or module, or in separate housing modules which are electrically connected to one another.

In embodiments, the power conversion arrangement is present in combination with a wireless charging device, wherein the power conversion arrangement is designed as a wireless charging station and the power conversion arrangement and the charging device together form an inductive power transmission system, in particular, for charging or discharging a battery of a vehicle.

In embodiments, the average effective edge angle is between 30° and 60°, in particular between 40° and 50°, in particular 45°.

In embodiments, the cutoff edge, beginning at the region of proximity, firstly in the region of proximity runs on average at a first edge angle, and subsequently it runs on average at a second edge angle, wherein the second edge angle is smaller than the first edge angle.

The effect of this is that in the region of proximity the distance of the cutoff edge to the fan wheel becomes larger than would be the case given a course of the cutoff edge in the same direction as in the remaining region. On account of this, the conveyed airflow therefore in the region of proximity experiences a comparatively less pronounced deflection and has a larger flow cross-section. On account of this, the flow experiences an improved detachment from the cut-off edge, with less eddying. This results in noticeable reduction of the acoustic emissions. Additionally to the aforedescribed compromise between emissions and conveying performance, given an equal conveying performance a reduction of the emissions is possible by way of this shape of the cutoff edge.

The characterisation of the course of the cutoff edge can be effected in the same projection as is described above with regard to the edge angle. If therefore one speaks of the angle of the cutoff at a certain location or as an average angle over a certain section of the cutoff edge, what is meant herewith is the angle in this projection. That which is stated remains valid if the projection direction and the projection plane are rotated slightly about the rotation axis.

In embodiments, the cutoff edge has the following course, beginning at the region of proximity, firstly in the region of proximity it runs at the first edge angle and subsequently in the remote region at a smaller angle. In particular, it runs in each case with a continuous transition between two regions with different edge angles. This continuous transition is advantageous with regard to the eddy formation.

In embodiments, the cutoff edge has an S-shaped course, beginning at the region of proximity, firstly in the region of proximity it runs at the first edge angle and subsequently at a smaller edge angle, and subsequently in the remote region again at a larger edge angle. In particular, in each case it runs with a continuous transition between two regions with different edge angles.

In embodiments, the cutoff edge has a U-shaped course, beginning at the region of proximity, in the region of proximity it firstly runs at the first edge angle and subsequently at a smaller edge angle, and subsequently in the remote region at at least one edge angle with a reverse sign. In particular, in each case it runs with a continuous transition between two regions with different edge angles.

In embodiments, with respect to an extension of the fan wheel considered in the direction of the rotation axis, hereinafter called height of the fan wheel, the region of proximity covers between 10% and 60% of the height of the fan wheel, in particular, between 20% and 40% of the height of the fan wheel.

### BRIEF DESCRIPTION OF THE DRAWINGS

The subject-matter of the invention is explained in more detail by way of preferred embodiment examples which are represented in the accompanying drawings. In each case shown schematically are:

FIG. 1 a garage with a vehicle which is parked therein;

FIG. 2 an arrangement of a cableless charging station and a cableless charging device;

FIG. 3 a radial fan of the cableless charging station;

FIGS. 4 and 5 perspective representations of the fan wheel in relation to a cutoff edge;

FIG. 6 a lateral view of the cutoff edge; and

FIGS. 7-9 different courses of a cut-off edge.

The reference numerals which are used in the drawings and their significance are listed in the list of reference numerals. Basically, in the figures, the same or functionally equal parts are provided with the same reference numerals.

### DETAILED DESCRIPTION

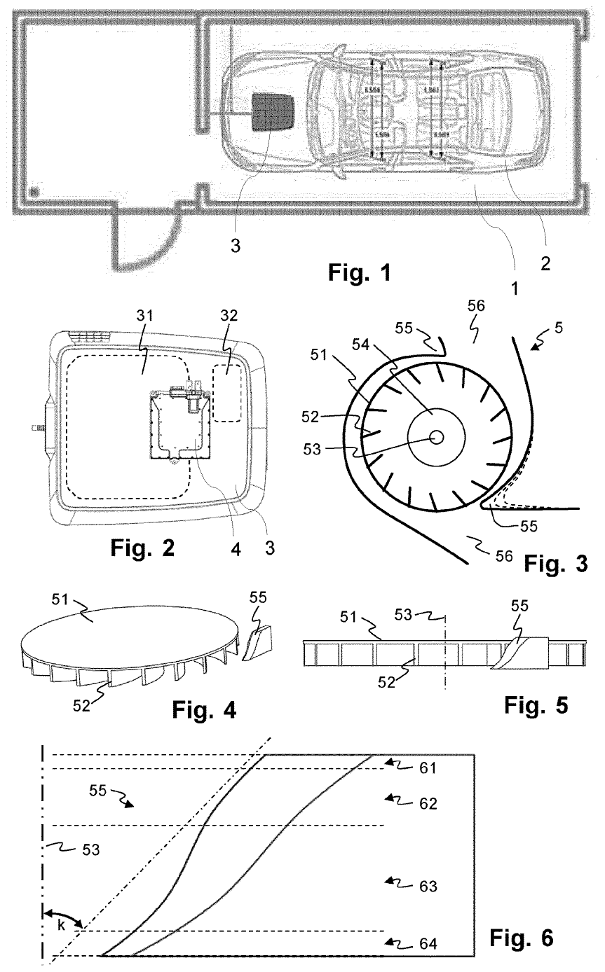

FIG. 1 in a plan view shows a garage 1 in which a vehicle 2 is parked above a cableless charging station 3 which is located outside the vehicle 2 and comprises an emitter for the transmission of an oscillating magnetic field. The charging station 3 is visible in the figure since the vehicle 2 is represented in a transparent manner. Such a charging solution is quite conformable and spares the driver from connecting and disconnecting a charging cable.

FIG. 2 is an enlargement of a detail from FIG. 1 and shows the cableless charging station 3 or GPM (ground pad module) as well as a cableless charging device 4 or CPM (car pad module) which is arranged above the charging station, for charging a traction battery, typically a high-voltage battery (HV) of the vehicle 2. The mentioned charging device 4 is installed into the vehicle 2. A magnetic subassembly 31 and an electronic subassembly 32 are schematically drawn as parts within the GPM 3. The magnetic subassembly comprises a coil and ferrite elements which heat up on operation of the GPM 3 and need to be cooled. The electronics subassembly 32 likewise needs to be cooled. The magnetic subassembly and electrical subassembly, as is shown here, can be arranged in a common housing. Alternatively, they can be arranged in separate housings or modules which are functionally coupled to one another for the exchange of electrical energy.

FIG. 3 schematically shows a radial fan 5 which is arranged in the GPM 3, for the air-cooling of subassemblies of the GPM 3, in particular, of the magnetic subassembly 31 and/or of the electronic subassembly 32. For this, cooling air is led over the ferrites and stranded wire of the magnetic subassembly 31 as well as over the electronic subassembly 32.

The radial fan 5 comprises a fan wheel 51 with a rotation axis 53 and blades 52. The fan wheel 51 conveys cooling air from an inlet region 54 to one or more outlet channels 56. At each outlet channel 56, the airflow at a cutoff edge 55 is led away from the fan wheel 51 into the outlet channel 56. Herein, eddies of the airflow arise at the cutoff edge 55 and these lead to noise emissions and worsen the efficiency of the radial fan 5.

FIGS. 4 and 5 shows perspective representations of only the fan wheel 51 in relation to the cutoff edge 55. FIG. 6 shows a lateral view of only the cutoff edge 55. The representation shows two inclined and slightly curved lines. The left one of these lines represents the outermost edge of the cutoff edge 55 which is visible in the view and the right one of these lines represents a transition between an arcuate region of the cutoff edge 55 and, connecting to this, a plane region of the wall of the outlet channel 56.

The cutoff edge 55 as a whole is inclined with respect to the rotation axis 53. An averaged course of the cutoff edge 55 is drawn in a dashed manner. The angle of this course with respect to the rotation axis 53 is denoted as an average angle or edge angle k. If only individual sections of the cutoff edge 55 are considered, then these can have a different average edge angle.

Beginning in the lower part of the cutoff edge 55 in FIG. 6, the cutoff edge 55 comprises a first edge region 64 which in a height region runs below a lower edge of the fan wheel 51. The cutoff edge 55 subsequently comprises a first edge region 64 in which the cutoff edge 55 firstly runs closely to the fan wheel 51 and then in manner distancing itself from this towards a remote region 62. A second edge region 61 which runs in a height region above an upper edge of the fan wheel 51 is subsequent to the remote region 62. If hereinafter one speaks of “height” then what is meant by this is the height as in FIG. 6, thus starting from the lower edge of the fan wheel 51. The inlet region 54 lies below the fan wheel 51. The inflowing air then gets into the fan wheel 51 from the bottom.

The region of proximity 63 can also be denoted as an effective region, and the average edge angle in the region of proximity 63 as the effective edge angle since it has a relatively large influence on the airflow and on the effects with regard to noise and conveying power which are entailed by this. The region of proximity, depending on the embodiment, can cover between 10% and 60% of the height of the fan wheel 51, in particular, between 20% and 40% of the height of the fan wheel 51.

In a projection onto a plane normal to the rotation axis 53, the cutoff edge 55 comprises a wedge-like cross section, as can be easily recognised in FIG. 3. With an increasing height of the cutoff edge 55, on the one hand it distances itself from the fan wheel 51, and on the other hand the curvature (considered in the mentioned projection) become increasingly smaller. This is represented in FIG. 3 by way of dashed height lines. The unbroken line corresponds to the course of the cutoff edge 55 at the height of the first edge region 64, the dashed lines to the course given an increasing height. The result of this is that with an increasing height the path of the airflow along the cutoff edge 55 becomes longer. Herewith, the deflection of the air becomes smaller. This reduced deflection in combination with the greater distance to the fan wheel 51 leads to the eddying of the air with the mentioned disadvantageous effects becoming smaller. The detachment of the airflow into the outlet channel 56 is therefore improved. This is effected at the cost of the conveying performance. According to predefined design criteria, a compromise between noise development and conveying performance can be selected by way of the selection of the effective edge angle.

An overall optimum can be improved with this compromise by way of a special shaping of the course of the cutoff edge 55. For this, the cutoff edge 55 according to FIG. 6 has an S-shaped course, beginning at the region of proximity 63, wherein in the region of proximity 63 it firstly runs at a first edge angle and subsequently at a smaller edge angle, and subsequently in the remote region 62 again at larger edge angle.

What is decisive here is the course with the firstly larger and then smaller edge angle. Herewith for example, compared to a straight cut-off edge 55, an improved conveying performance can be achieved given an equal noise formation. Alternatively, given an equal conveying performance, a lower noise development can be achieved. The optimum of the course can be determined way of numerical simulations.

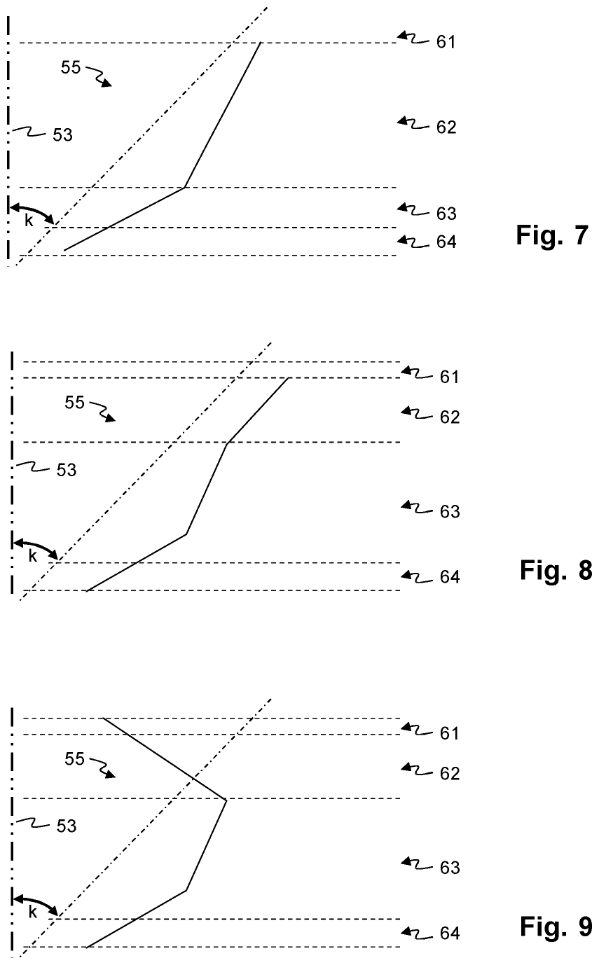

The course of the cutoff edge 55 over the complete height can be designed differently, as is shown in FIGS. 7-9. These each schematically show straight sections, corresponding to the average edge angles of the respective sections. Typically, the transitions between the sections are smoothed or rounded, thus with continuous transitions as in FIG. 6.

In FIG. 7, the cutoff edge 55 runs at the first edge angle in the whole region of proximity 63 and subsequently at a smaller edge angle in the remote region 62. In FIG. 8, the cutoff edge 55 has an S-shaped course as has already been described above in a detailed manner. In FIG. 9, the cutoff edge 55 has a U-shaped course, beginning in the region of proximity 63 with a first edge angle and subsequently with a smaller edge angle, and subsequently in the remote region 62 with at least one edge angle with a reverse sign.

According to further embodiments, the cutoff edge 55 in the remote region runs at least approximately in a mirror-imaged manner to the region of proximity 63.

### LIST OF REFERENCE NUMERALS

1 garage
2 vehicle
3 GPM
31 magnetic subassembly
32 electronic subassembly
4 CPM
5 radial fan
51 fan wheel
52 blades
53 rotation axis
54 inlet region
55 cutoff edge
56 outlet channel
61 first edge region
62 remote region
63 region of proximity
64 second edge region

1. A power conversion arrangement for the conversion of electrical power of an electrical feed current into electromagnetic power of an oscillating electromagnetic field, the power conversion arrangement comprising:
a magnetic subassembly for receiving or delivering an electrical alternating current and/or for emitting an oscillating electromagnetic field,
an electronic subassembly for receiving the electrical feed current and for its conversion into an electrical alternating current for the supply of the magnetic subassembly, and
a heat dissipation means for dissipating heat which is generated by the electronic subassembly and/or the magnetic subassembly during its respective power conversion operation,
wherein the heat dissipation means comprise at least one radial fan arranged for the conveying air for cooling the magnetic subassembly and/or the electronic subassembly, and
wherein the radial fan with a fan wheel conveys the air into at least one outlet channel past at least one cutoff edge, wherein the cutoff edge with regard to a rotation axis of the radial fan and in a region of proximity to the fan wheel is angled about an angle, hereinafter denoted as an effective edge angle (k), of at least twenty degrees.

2. The power conversion arrangement according to claim 1, in combination with a wireless charging device, wherein the power conversion arrangement is designed as a wireless charging station, and the power conversion arrangement and the charging device together form an inductive power transmission system for charging or discharging a battery of a vehicle.

3. The power conversion arrangement according to claim 1, wherein the average effective edge angle (k) is in a range of 30° to 60°.

4. The power conversion arrangement according to claim 1, wherein the cutoff edge, beginning at the region of proximity, in the region of proximity firstly runs on average at a first edge angle and subsequently runs on average at a second edge angle, wherein the second edge angle is smaller than the first edge angle.

5. The power conversion arrangement according to claim 4, wherein the cutoff edge has the following course, beginning at the region of proximity, it firstly runs at the first edge angle in the region of proximity and subsequently at a smaller edge angle in the remote region, and in each case with a continuous transition between two regions with different edge angles.

6. The power conversion arrangement according to claim 4, wherein the cutoff edge has an S-shaped course, beginning at the region of proximity, in the region of proximity it firstly runs at the first edge angle and subsequently at a smaller edge angle, and subsequently in the remote region again at a larger edge angle, and in each case with a continuous transition between two regions with different edge angles.

7. The power conversion arrangement according to claim 4, wherein the cutoff edge has a U-shaped course, beginning at the region of proximity, in the region of proximity it firstly runs at the first edge angle and subsequently at a smaller edge angle, and subsequently in the remote region at at least one edge angle with a reverse sign, and in each case with a continuous transition between two regions with different edge angles.

8. The power conversion arrangement according to claim 4, wherein with respect to an extension of the fan wheel considered in the direction of the rotation axis, hereinafter called height of the fan wheel, the region of proximity covers between 10% and 60% of the height of the fan wheel.

9. The power conversion arrangement according to claim 8, wherein the region of proximity covers between 20% and 40% of the height of the fan wheel.

10. The power conversion arrangement according to claim 5, wherein with respect to an extension of the fan wheel considered in the direction of the rotation axis, hereinafter called height of the fan wheel, the region of proximity covers between 10% and 60% of the height of the fan wheel.

11. The power conversion arrangement according to claim 10, wherein the region of proximity covers between 20% and 40% of the height of the fan wheel.

12. The power conversion arrangement according to claim 6, wherein with respect to an extension of the fan wheel considered in the direction of the rotation axis, hereinafter called height of the fan wheel, the region of proximity covers between 10% and 60% of the height of the fan wheel.

13. The power conversion arrangement according to claim 12, wherein the region of proximity covers between 20% and 40% of the height of the fan wheel.

14. The power conversion arrangement according to claim 3, wherein the average effective edge angle (k) is in a range of 40° to 50°.

15. The power conversion arrangement according to claim 1, wherein the average effective edge angle (k) is 45°.
